(19) United States
(12) Patent Application Publication
(10) Pub. No.: US 2005/0274407 A1
(43) Pub. Date: Dec. 15, 2005

(54) Indoor photovoltaic energy system

(76) Inventor: William Sims Curry, Chico, CA (US)

Correspondence Address: William S. Curry, 17 Northwood Commons Pl., Chico, CA, 95973-7213, US

(21) Appl. No.: 10/864,711

(22) Filed: Jun. 9, 2004

(51) Int. Cl. H01L 31/00

(52) U.S. Cl. 136/244; 136/293

(57) ABSTRACT

An indoor photovoltaic energy system to provide a renewable energy source for buildings located in urban areas or other locations where there is insufficient land or roof area for mounting a sufficient number of photovoltaic panels to general a significant amount of electric energy. This concept is especially beneficial for multi-story buildings with a low ratio of roof space or available ground space per square foot of building space. This system uses standard indoor electric lighting fixtures as well as any available natural light through windows, skylights or other building openings for the light source that is converted to electric power. The direct current electric power generated by the photovoltaic panels is converted to more usable alternating current electric power by an inverter.

### CROSS-REFERENCE TO RELATED APPLICATIONS

Non-Applicable

### FEDERALLY SPONSORED RESEARCH

Non-Applicable

### SEQUENCE LISTING OR PROGRAM

Non-Applicable

### BACKGROUND OF THE INVENTION

1. Field of Invention

This invention relates to the generation of electricity through the use of photovoltaic panels, specifically from indoor light sources such as indoor electrical office lighting, skylights, or clear (such as glass) roofs.

2. Background of the Invention

Originally photovoltaic energy systems relied on solar energy collected on roof or ground mounted photovoltaic panels that generate direct current electric power by exposure to sunlight. The direct current electric power was then converted to alternating current electric power to permit use of electric power compatible with electric power provided through standard electric grids. The difficulty of generating electric power in this manner is that considerable roof space or ground space is required for installation of the photovoltaic panels that are required to generate sufficient electric power to provide all or a portion of the electric requirements for a building. The problem of the lack of suitable space for mounting the photovoltaic panels is compounded in urban areas where there is a greater demand for electric power yet where little space is available due to lack of available space due to urban development. The demand is greater and the available outdoor space is further restricted where multi-story buildings exist. Existing photovoltaic panels and inverters are highly efficient and practical. Such advances in the art for outdoor systems make it practical to install an indoor photovoltaic power system that can economically generate a portion of the electric energy used to energize office lighting fixtures as well as generate electric energy from solar light that may be available in the indoor environment.

### BACKGROUND OF THE INVENTION—OBJECTS AND ADVANTAGES

Accordingly, several objects and advantages of my invention are the generation of electric power from photovoltaic panels that are mounted on the inside of a building; generation of electric power in an urban setting where there is insufficient roof space or ground space for mounting outdoor photovoltaic panels; generation of electric power from needed lighting on all floors in a multi-story building; generation of electric power from indoor electrical lighting as well as from indoor solar lighting provided through windows, skylights, clear roofing, or atriums; indoor photovoltaic panels that can be installed indoors on top of wall mounted storage units, free standing storage units, most other office furniture, or mounted directly on a wall, ceiling, or free standing on a floor; and capitalizes on the improved technology that evolved to make outdoor photovoltaic energy systems extremely efficient to achieve the economically feasible generation of electric energy indoors.

Further objects and advantages of my invention will become apparent from a consideration of the drawings and ensuing description.

### SUMMARY

My invention is an indoor photovoltaic energy system that generates electric energy from any source of indoor light whether it originated from electric lighting or natural sources emanating through windows, skylights, clear roofing, atriums, or any other source. This invention permits photovoltaic electric generation in urban areas or any other locations where there is insufficient ground or roof mounting space for conventional outdoor photovoltaic energy systems. The development of this approach became economically feasible through the efficiency gains achieved through improved photovoltaic panels and inverters developed for outdoor photovoltaic energy systems.

### DRAWINGS—FIGURES

FIG. 1 is a side view illustrating a typical office layout that includes office lighting fixtures, one photovoltaic panel mounted atop a wall mounted storage unit, another photovoltaic panel mounted atop a floor standing office filing unit, and a miscellaneous piece of floor standing office furniture. This drawing shows the photovoltaic panels angled to receive significant light from the office lighting fixtures. However, the panels can be angled in any beneficial orientation including vertical or horizontal. A horizontal mounting might be advantageous for receiving light from a window.

FIG. 2 is a side view identical to FIG. 1 with the exception that the photovoltaic panel on the left is mounted directly on the wall without the benefit of the wall mounted storage unit.

FIG. 3 is a side view illustrating an eight story building with indoor photovoltaic panels in each of the offices. The photovoltaic panels would be wired to the inverter apparatus shown to the right of the building on its own concrete pad. The inverter apparatus is required to convert the direct current electric power generated by the photovoltaic panels into alternating current electric power that could be transmitted to the local power grid or alternate destination.

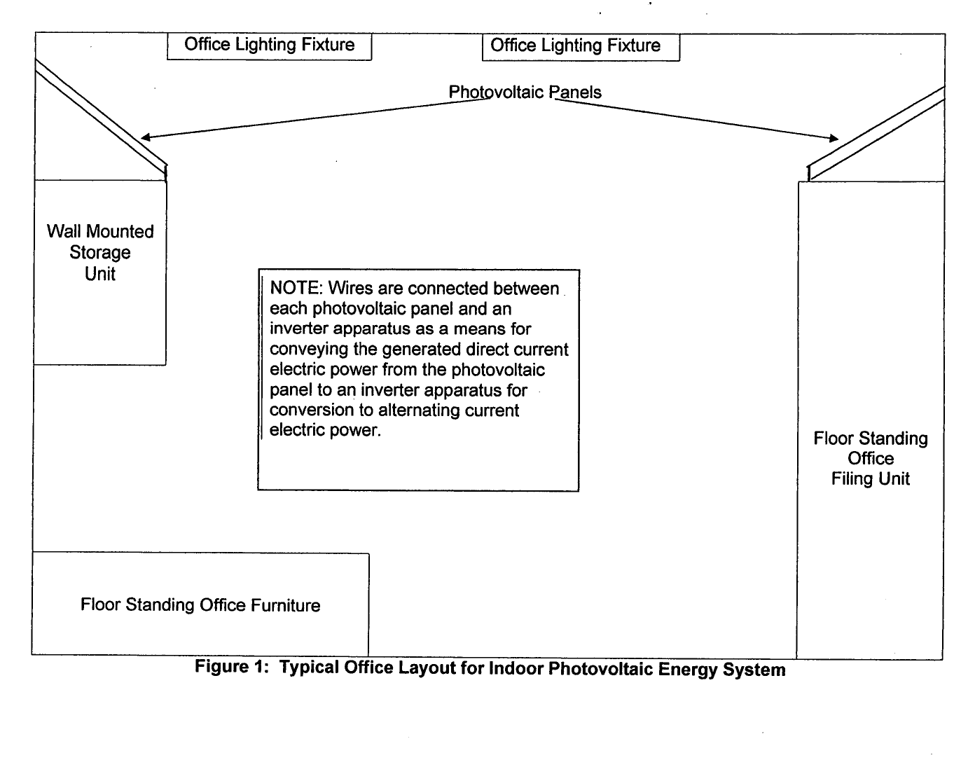

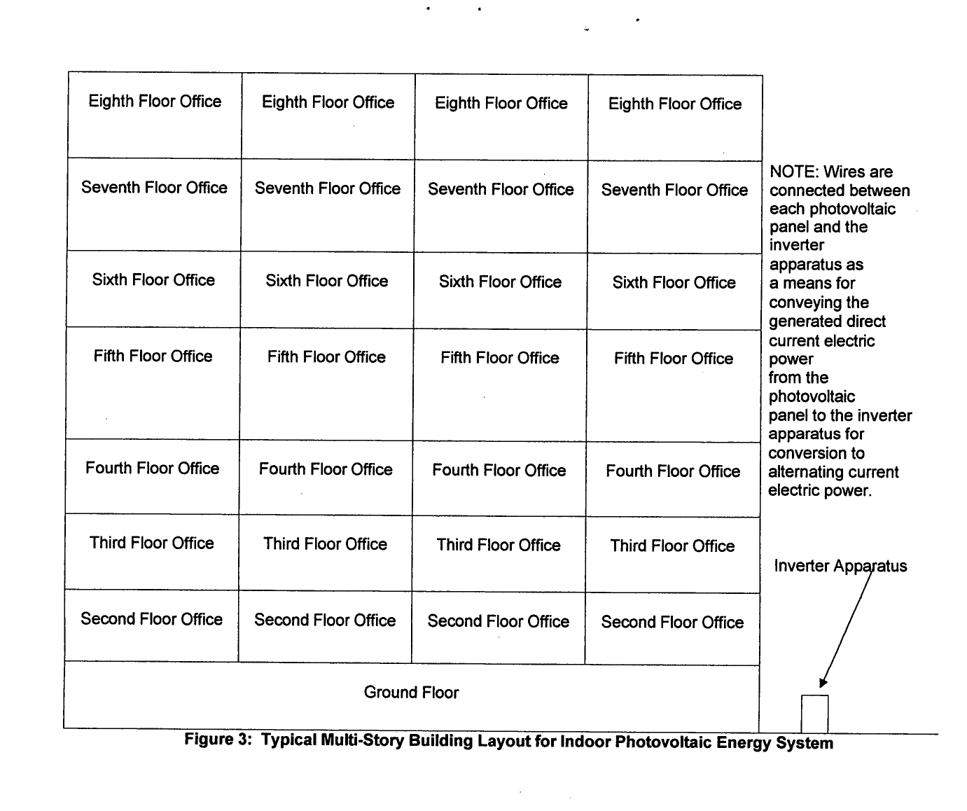

### DETAILED DESCRIPTION—FIGS 1 AND 3—PREFERRED EMBODIMENT

A preferred embodiment of the installation of the present invention is illustrated in FIG. 1 and FIG. 3. FIG. 1 shows the photovoltaic panels mounted atop office equipment and angled towards the office lighting fixtures to gain maximum exposure of the light emanating from the lighting fixtures. However, the photovoltaic panels can be mounted at any other angle, or directly mounted on a wall, free standing on the floor, or mounted in any other manner in which they can utilize indoor light from natural or artificial sources to generate electric power.

FIG. 3 shows an eight story building with photovoltaic panels mounted on all floors of the building and connected by wiring to a single inverter apparatus. However, the photovoltaic panels can be mounted inside a building of any size and any number of stories. The photovoltaic panels can be mounted in all the rooms or only in selected rooms in the building. Although FIG. 3 shows just one inverter for the entire building, the number of inverters would normally be determined by the capacity of the inverter and the level of electric energy generated by the photovoltaic panels. The number of inverters, therefore, would be determined by the amount of electric energy generated within the building. A large building, where considerable electric energy is generated, multiple inverters would likely be required for one building. In smaller buildings, or in buildings where a lesser amount of electric energy is generated, one inverter may suffice for one or multiple buildings.

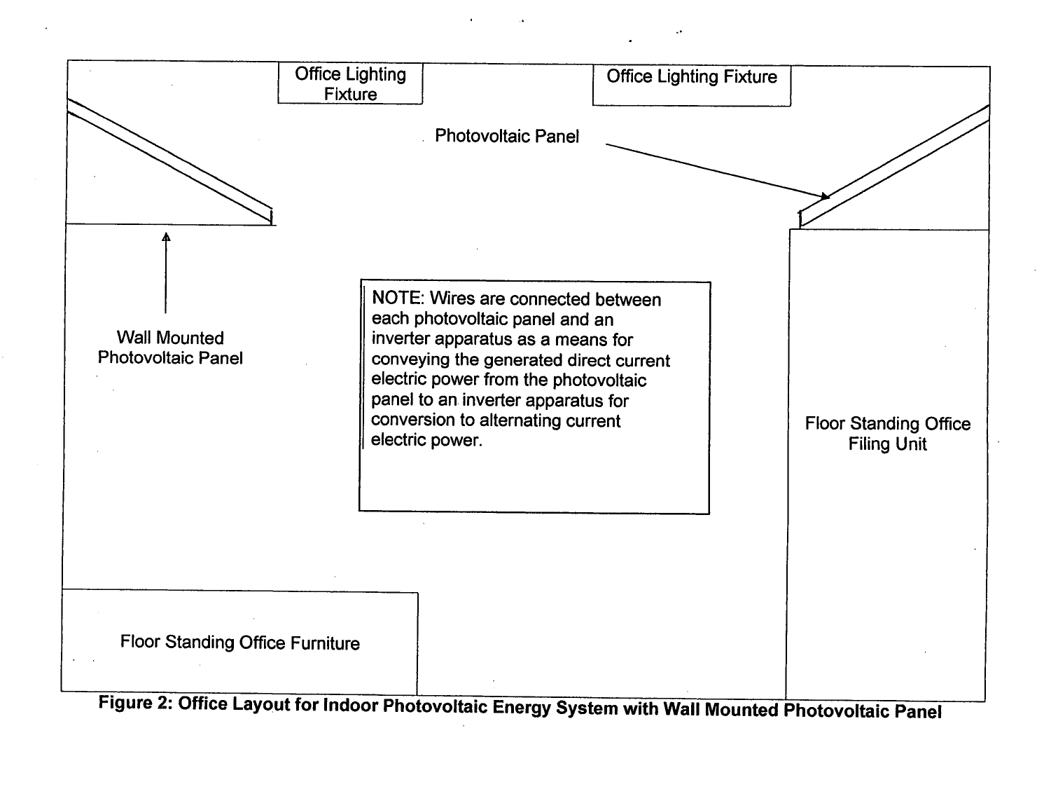

FIG. 2—Additional Embodiment

FIG. 2 shows an additional embodiment wherein the photovoltaic panel, rather than being mounted atop office furniture or atop other office equipment, is attached directly to a wall.

My invention operates exactly as do outdoor photovoltaic energy systems in common use throughout the world. The only exception is that rather than rely solely on sunlight, the photovoltaic panels in this indoor system would use light from ordinary office lighting fixtures, as well as any available sunlight from windows or other natural light sources, to generate direct current electric power. The conversion of the direct current electric power would be transformed into alternating current electric power with an inverter just as with outdoor photovoltaic energy systems.

Thus the reader will see that the indoor photovoltaic energy system will provide a renewable energy source for buildings that are located in urban areas or other locations where there is insufficient land or roof area available for mounting outdoor photovoltaic systems. While my above description contains many specificities, these should not be construed as limitations on the scope of the invention, but rather as an exemplification of one preferred embodiment thereof. Many other variations are possible. For example, the figures depict office space but could just as well have shown a laboratory, manufacturing facility, warehouse, retail outlet, dining establishment, aircraft hangar, or any other indoor applications.

Accordingly, the scope of the invention should be determined not by the embodiments illustrated, but by the appended claims and their legal equivalents.

1. Photovoltaic panels mounted inside a building wherein said photovoltaic panels are exposed to artificial and/or natural light thus enabling said photovoltaic panels to generate direct current electric power that is in-turn transmitted through connected wires to an inverter or inverters that convert the direct current electric power into alternating current electric power, the improvement wherein renewable electric power is generated inside a building where there is insufficient ground or roof space to provide a conventional outdoor photovoltaic energy system.

2. The mounting of said photovoltaic panels may be atop furniture or equipment within the building, mounted on the walls of the building or placed on the floor of the building.

3. Numerous said photovoltaic panels may be connected by wire to transmit direct current electric power to one or more said inverters.

4. Said photovoltaic panels may be mounted in one or more rooms on one or more stories in a multi-story building to maximize the generation of electric energy by said photovoltaic panels.
